(19) United States
(12) Patent Application Publication
(10) Pub. No.: US 2003/0154906 A1
(43) Pub. Date: Aug. 21, 2003

(54) Process for producing a highly doped silicon single crystal

(75) Inventors: Martin Weber, Kastl (DE); Erich Gmeilbauer, St. Pantaleon (AT); Robert Vorbuchner, Burghausen (DE)

Correspondence Address: COLLARD & ROE, P.C., 1077 Northern Boulevard, Roslyn, NY, 11576, US

(73) Assignee: WACKER SILTRONIC AG

(21) Appl. No.: 10/371,493

(22) Filed: Feb. 20, 2003

(30) Foreign Application Priority Data
Feb. 21, 2002 (DE) 102 07 284.1

(51) Int. Cl. C30B 15/00; C30B 21/06; C30B 27/02; C30B 28/10; C30B 30/04

(52) U.S. Cl. 117/13; 117/14; 117/15

(57) ABSTRACT

A process for producing a highly doped silicon single crystal by pulling the single crystal from a molten material which contains dopant and is held in a rotating crucible. Growth fluctuations during the pulling of the single crystal are limited to an amount of −0.3 mm/min to 0.3 mm/min.

### BACKGROUND OF THE INVENTION

1. Field of the Invention

The present invention relates to a process for producing a highly doped silicon single crystal by pulling the single crystal from a molten material which contains dopant and is held in a rotating crucible.

2. The Prior Art

Czochralski crucible pulling (CZ crucible pulling process) and the float zone pulling process are methods which are customarily used for the production of high-purity single crystals, in particular single-crystal silicon ingots. In the case of crucible pulling, the monocrystalline or polycrystalline semiconductor fragments which are provided in order to produce the molten material are generally placed in a melting crucible. Then, the crucible temperature is increased by heating until the crucible contents gradually pass into the molten state. Finally, a seed crystal is placed against the molten material and a single crystal, which in part grows in cylindrical form, is pulled from the molten material, the crucible and the single crystal generally being rotated. The single crystal comprises the seed crystal, a dash neck which is pulled first, a starting cone which is pulled next, as transition to the cylindrical section, the cylindrical section itself and an end cone. The cylindrical section of the single crystal is generally processed further to form semiconductor wafers.

The defect distribution and the oxygen precipitation are influenced by the crystal growth rate. For highly doped crystals—in particular doped with arsenic, antimony, pure phosphorus or boron—the oxygen precipitation can be adjusted by targeted addition of foreign materials, such as nitrogen or carbon. For this purpose, nitrogen concentrations in the range from 1*10¹³ to 5*10¹⁵ l/cm³ and a carbon content of over 2*10¹⁶ l/cm³ are used.

A highly doped single crystal contains the dopant in a concentration which is close to the saturation concentration. The single crystal and semiconductor wafers which are cut from it have electrical properties with low resistance, on account of the high dopant concentration. It is difficult to produce a silicon single crystal of this type, since the incorporation of a relatively high concentration of dopant considerably increases the risk of dislocations being formed when the single crystal is being pulled. On the other hand, there is an increasing demand for low-resistance semiconductor wafers with diameters of 200 mm and above. However, on account of the abovementioned problem, these wafers, unlike high-resistance (low-dopant) semiconductor wafers, can scarcely be produced economically. Dislocations may spread in the single crystal and make it unusable. The ingot which has been pulled then has to be remelted and a new, difficult attempt to pull a single crystal has to be started. However, the number of possible attempts to pull the crystal is limited, for example, by the service life of the melting crucible, and consequently it may no longer be possible to pull a defect-free single crystal.

### SUMMARY OF THE INVENTION

Therefore, it is an object of the present invention to provide a process which allows economic production of dislocation-free silicon single crystals which are highly doped.

The above object is achieved according to the present invention by providing a process for producing a highly doped silicon single crystal by pulling the single crystal from a molten material which contains dopant and is held in a rotating crucible, wherein growth fluctuations during the pulling of the single crystal are limited to an amount of −0.3 mm/min to 0.3 mm/min.

Surprisingly, it is possible to significantly reduce the frequency of dislocations if the growth fluctuations are kept within the proposed range. The limits to the range represent maximum permissible deviations from a predetermined growth rate. The controlled avoidance of fluctuations in the growth rate apparently allows more homogeneous incorporation of the dopant. Thus local stresses which cause dislocations occur much less frequently in the growing single crystal.

The present invention is advantageously used to produce silicon single crystals, in particular those which are doped with a substance such as arsenic, antimony or phosphorus. When these crystals are doped with arsenic, they have a resistivity of preferably at most 3 mOhm*cm, and particularly preferably at most 2 mOhm*cm. When these crystals are doped with antimony, they have a resistivity of preferably at most 20 mOhm*cm, and particularly preferably at most 15 mOhm*cm. When these crystals are doped with phosphorus, they have a resistivity of preferably at most 2 mOhm*cm, particularly preferably at most 1.5 mOhm*cm. If the growth fluctuations are limited as described above, dislocation-free crystal growth is possible even in the highly doped range, close to the saturation limit of the dopant.

The desired high dopant concentrations, which lead to low resistivities, are generally only reached toward the rear region of the cylindrical section of the single crystal, on account of the segregation. Therefore, the particular advantage of the invention manifests itself in particular in this phase of the pulling operation. However, the targeted suppression of growth fluctuations is also advantageous for the dislocation-free pulling of the dash neck, starting cone or end cone.

Undesirable growth fluctuations can be limited, for example, by controlling the supply of thermal energy to the phase boundary between the molten material and the growing single crystal. This can be achieved, for example, by a fine-tuned stipulated heating output. The supply of heat to the growing single crystal can also be controlled efficiently by means of the crucible rotation. Growth fluctuations can also be limited by applying a magnetic field which influences the convection in the molten material. Low pulling rates are preferable. These low pulling rates are those at which the crystal movement during pulling of the single crystal is preferably no more than 0.8 mm/min, and particularly preferably no more than 0.6 mm/min. Finally, the crystal movement itself can also be used as a parameter for controlling the growth rate and for reducing growth fluctuations. It is particularly preferable to combine two or more of the abovementioned influencing possibilities to limit growth fluctuations and if appropriate to control the diameter of the cylindrical section of the single crystal.

### BRIEF DESCRIPTION OF THE DRAWINGS

Other objects and features of the present invention will become apparent from the following detailed description considered in connection with the accompanying drawings which disclose several embodiments of the present invention. It should be understood, however, that the drawings are designed for the purpose of illustration only and not as a definition of the limits of the invention.

The effect of the invention is explained below with reference to figures, which show the result of pulling tests in which arsenic-doped silicon single crystals were produced with a diameter of 200 mm using the Czochralski method, in which:

FIG. 1 shows an axial resistivity profile of the silicon single crystal as a function of ingot length; and

FIG. 2 shows growth rate as a function of ingot length.

### DETAILED DESCRIPTION OF PREFERRED EMBODIMENTS

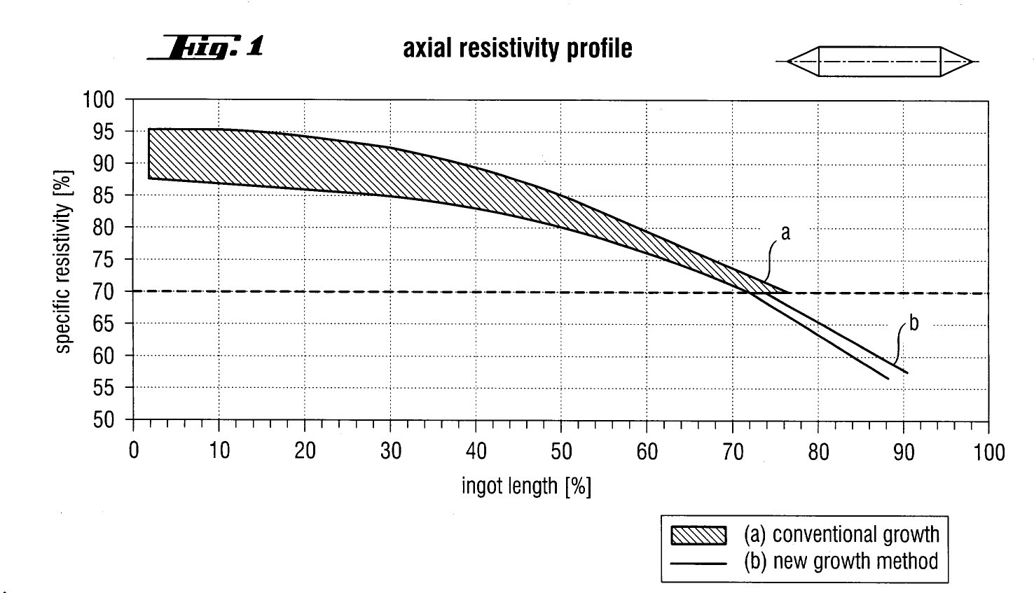

FIG. 1 shows a comparative consideration of the resistivity as a function of the length of the single crystal. It can be seen that with a single crystal which has been pulled conventionally (a), further dislocation-free growth was no longer possible after a certain resistivity had been reached. On the other hand, if pulling was carried out, under otherwise identical conditions, in such a way that growth fluctuations remained within the claimed range (b), it was even possible to pull ingot parts with a low resistivity of below 2.0 mOhm*cm without dislocations.

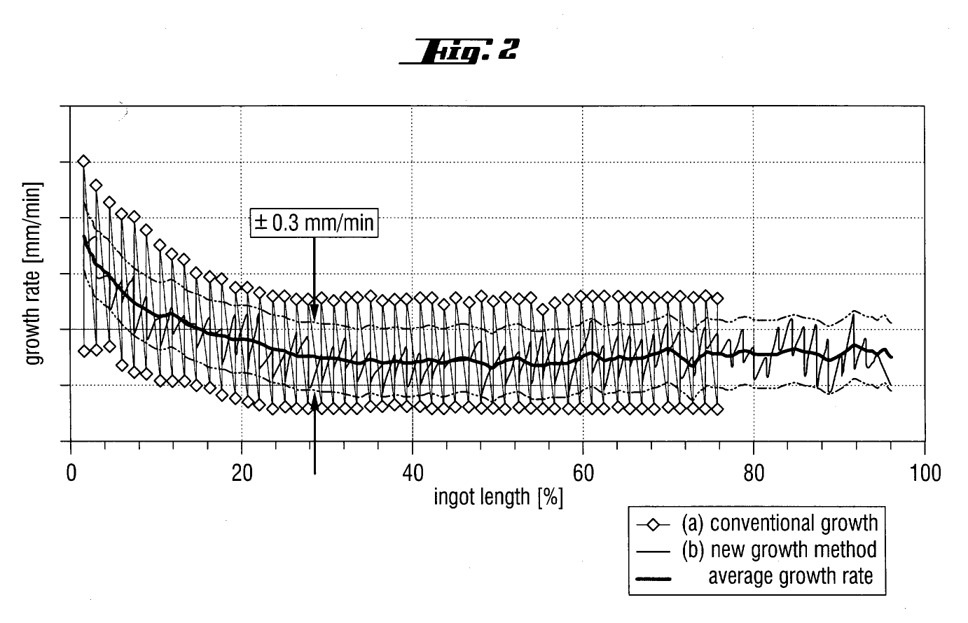

The growth rate as a function of the length of the silicon single crystal is plotted in FIG. 2 for the same pulling tests. It can be seen that even a slight failure to observe the recommended limits for the growth fluctuations has disadvantageous consequences. It was no longer possible to achieve the full single-crystal ingot length which was intended.

Accordingly, while a few embodiments of the present invention have been shown and described, it is to be understood that many changes and modifications may be made thereunto without departing from the spirit and scope of the invention as defined in the appended claims.

What is claimed is:

1. A process for producing a highly doped silicon single crystal comprising
pulling the silicon single crystal from a molten material which contains dopant and is held in a rotating crucible; and
limiting growth fluctuations during the pulling of the silicon single crystal to an amount of −0.3 mm/min to 0.3 mm/min.

2. The process as claimed in claim 1, comprising
limiting the growth fluctuations by controlling a supply of thermal energy to a phase boundary between the molten material and a growing silicon single crystal.

3. The process as claimed in claim 1, comprising
limiting the growth fluctuations by selecting a low pulling rate.

4. The process as claimed in claim 1, comprising
limiting the growth fluctuations by applying a magnetic field which influences convection in the molten material.

5. The process as claimed in claim 1, comprising
limiting the growth fluctuations by controlling rotation of the crucible.

6. The process as claimed in claim 1, comprising
limiting the growth fluctuations by controlling crystal movement which takes place during the pulling of the silicon single crystal.

7. The process as claimed in claim 1,
wherein the molten material is doped with a substance selected from the group consisting of arsenic, antimony and phosphorus.
